(19) United States
(12) Patent Application Publication
(10) Pub. No.: US 2016/0379915 A1
(43) Pub. Date: Dec. 29, 2016

(54) SEMICONDUCTOR DEVICE AND MANUFACTURING METHOD THEREOF

(71) Applicant: Amkor Technology, Inc., Tempe, AZ (US)

(72) Inventors: Wang Gu Lee, Goyang-si (KR); Jong Sik Paek, Incheon (KR); Sung Geun Kang, Bucheon-si (KR); Yong Song, Seoul (KR); Moo Gun Lee Lee, Hwaseong-si (KR); Na Rae Jang, Incheon (KR)

(21) Appl. No.: 15/149,158

(22) Filed: May 8, 2016

(30) Foreign Application Priority Data
Jun. 23, 2015 (KR) 10-2015-0089245

(51) Int. Cl. H01L 23/498; H01L 21/48

(52) U.S. Cl. CPC H01L 23/498; H01L 23/49827; H01L 23/49816; H01L 21/486; H01L 21/4846

(57) ABSTRACT

A semiconductor device and a method of manufacturing a semiconductor device. As a non-limiting example, various aspects of this disclosure provide a semiconductor device, and method of manufacturing thereof, that comprises a redistribution structure formed on a stiffening layer.

### CROSS-REFERENCE TO RELATED APPLICATIONS/INCORPORATION BY REFERENCE

The present application makes reference to, claims priority to, and claims the benefit of Korean Patent Application No. 10-2015-0089245, filed on Jun. 23, 2015, in the Korean Intellectual Property Office and titled “SEMICONDUCTOR DEVICE,” the contents of which are hereby incorporated herein by reference in their entirety.

### BACKGROUND

Present semiconductor devices and methods for manufacturing semiconductor devices are inadequate, for example resulting in excess cost, decreased reliability, or package sizes that are too large. Further limitations and disadvantages of conventional and traditional approaches will become apparent to one of skill in the art, through comparison of such approaches with the present disclosure as set forth in the remainder of the present application with reference to the drawings.

### BRIEF DESCRIPTION OF SEVERAL VIEWS OF THE DRAWINGS

FIG. 1 is a cross-sectional view of a semiconductor device according to an embodiment of the present disclosure.

FIG. 2A is an enlarged cross-sectional view illustrating a conductive via formed in a stiffener using a damascene process, and FIG. 2B is an enlarged cross-sectional view illustrating a through silicon via formed on a substrate using a plasma etching process.

FIG. 3 is a cross-sectional view of a semiconductor device according to another embodiment of the present disclosure.

FIG. 4 is a cross-sectional view of a semiconductor device according to still another embodiment of the present disclosure.

FIGS. 5A to 5K are cross-sectional views sequentially illustrating a method of manufacturing a semiconductor device according to still another embodiment of the present disclosure.

FIGS. 6A to 6G are cross-sectional views sequentially illustrating a method of manufacturing a semiconductor device according to still another embodiment of the present disclosure.

### SUMMARY

Various aspects of this disclosure provide a semiconductor device and a method of manufacturing a semiconductor device. As a non-limiting example, various aspects of this disclosure provide a semiconductor device, and method of manufacturing thereof, that comprises a redistribution structure formed on a stiffening layer.

### DETAILED DESCRIPTION OF VARIOUS ASPECTS OF THE DISCLOSURE

The following discussion presents various aspects of the present disclosure by providing examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.”

The terminology used herein is for the purpose of describing particular examples only and is not intended to be limiting of the disclosure. As used herein, the singular forms are intended to include the plural forms as well, unless the context clearly indicates otherwise. It will be further understood that the terms “comprises,” “includes,” “comprising,” “including,” “has,” “have,” “having,” and the like when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, various spatial terms, such as “upper,” “above,” “lower,” “below,” “side,” and the like, may be used in distinguishing one element from another element in a relative manner. It should be understood, however, that components may be oriented in different manners, for example a semiconductor device may be turned sideways so that its “top” surface is facing horizontally and its “side” surface is facing vertically, without departing from the teachings of the present disclosure.

In the drawings, the thickness or size of layers, regions, and/or components may be exaggerated for clarity. Accordingly, the scope of this disclosure should not be limited by such thickness or size. Additionally, in the drawings, like reference numerals may refer to like elements throughout the discussion.

It will also be understood that when an element A is referred to as being “connected to” or “coupled to” an element B, the element A can be directly connected to the element B or indirectly connected to the element B (e.g., an intervening element C (and/or other elements) may be present between the element A and the element B).

Various aspects of the present disclosure relates to a semiconductor device and a manufacturing method thereof.

In general, a semiconductor device manufactured by installing a semiconductor die onto an interposer and stacking the interposer on another semiconductor die or substrate (e.g., a package substrate, etc.) may be referred to herein as a 2.5D package. A 3D package is generally obtained by directly stacking one semiconductor die onto another semiconductor die or substrate without utilizing an interposer.

The interposer of the 2.5D package may include a plurality of through silicon vias so as to permit an electrical signal to flow between an upper semiconductor die and a lower semiconductor die or substrate.

Various aspects of the present disclosure provide a semiconductor device, and a manufacturing method thereof, having improved reliability by reinforcing mechanical stiffness through a redistribution layer (or structure) formed on a stiffener.

According to an aspect of the present disclosure, there is provided a semiconductor device including an interposer including a stiffener having a conductive via and a redistribution layer (or structure) connected to the conductive via, and a semiconductor die connected to the redistribution layer (or structure) of the interposer.

As described herein, one embodiment of the present disclosure provides a semiconductor device having improved reliability by reinforcing mechanical stiffness through a redistribution structure (or layer) formed on a stiffener. That is to say, according to various aspects of the present disclosure, a redistribution layer (or structure) is formed on a stiffener made of a material having high hardness and/or strength, such as silicon, glass or ceramic, to reinforce the mechanical stiffness of the interposer, compared to the conventional interposer, thereby facilitating handling of the interposer in the course of manufacturing the semiconductor device and improving mechanical reliability of the completed semiconductor device. In particular, according to various aspects of the present disclosure, the mechanical stiffness of the interposer is reinforced, thereby suppressing interfacial delamination between an under bump metal and a conductive bump.

Another embodiment of the present disclosure provides a semiconductor device, which can reduce a manufacturing cost of an interposer by forming a conductive via using a relatively inexpensive damascene process, instead of a through silicon via formed using a relatively expensive plasma etching or laser drilling process. That is to say, according to various aspects of the present disclosure, a trench is formed in a stiffener and a conductive layer is then filled in the trench, followed by removing a region of the stiffener using a planarization process or a grinding process, thereby completing the conductive via electrically connecting top and bottom surfaces of the stiffener. Therefore, according to various aspects of the present disclosure, the conductive via capable of performing the same function as the conventional through silicon via can be manufactured at low cost without using the relatively expensive plasma etching or laser drilling process.

Still another embodiment of the present disclosure provides a semiconductor device including a conductive pillar having a fine pitch by forming a conductive pillar on an interposer using a damascene process. That is to say, according to various aspects of the present disclosure, a trench is formed in a stiffener and a conductive layer is then filled in the trench, followed by removing a predetermined region of the stiffener using a planarization or grinding process and an etching process, thereby completing the conductive via connecting top and bottom surfaces of the stiffener and a conductive pillar integrally formed in the conductive via. Therefore, according to various aspects of the present disclosure, the conductive pillar having a fine pitch can be formed at low cost.

Hereinafter, examples of embodiments of the disclosure will be described in detail with reference to the accompanying drawings such that they can easily be made and used by those skilled in the art.

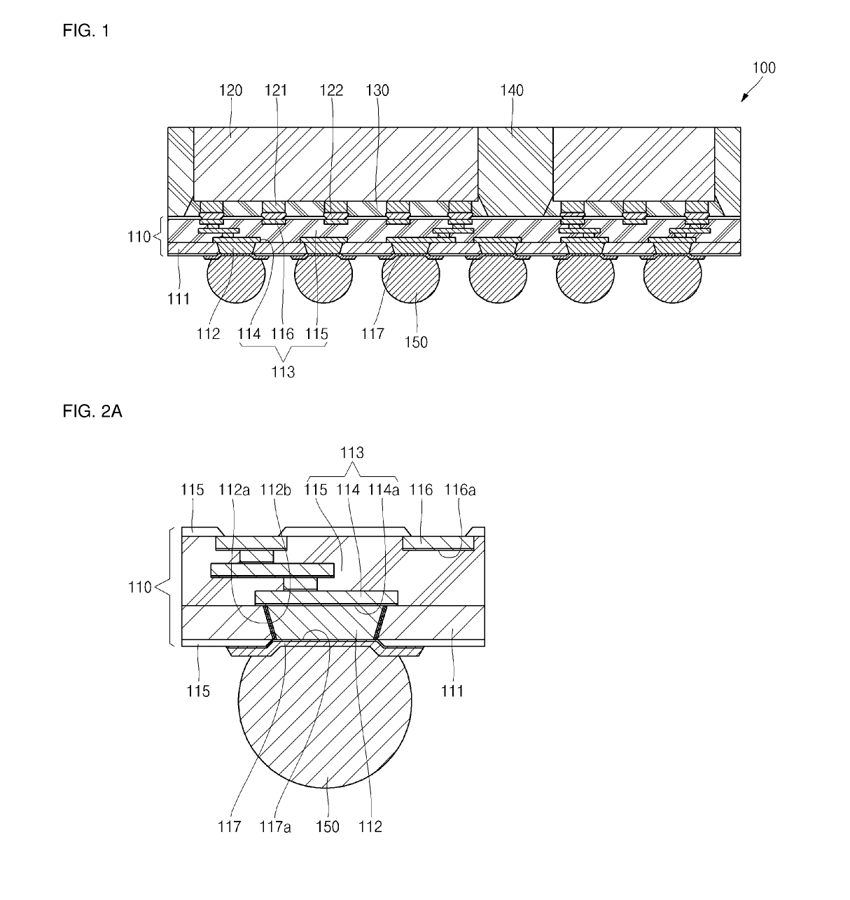

Referring to FIG. 1, a cross-sectional view of a semiconductor device (100) according to an embodiment of the present disclosure is illustrated.

As illustrated in FIG. 1, the semiconductor device 100 according to an embodiment of the present disclosure includes an interposer 110, a semiconductor die 120, an underfill 130, an encapsulant 140 and a conductive bump 150.

The interposer 110 includes a stiffener 111 having a conductive via 112, a redistribution layer 113 (or redistribution structure) including a redistribution pattern 114, and an under bump metal 117. The interposer 110 permits an electrical signal to flow between the semiconductor die 120 and a circuit board (or an external device).

The stiffener 111 has a substantially planar top surface and a substantially planar bottom surface opposite to the top surface and may be made of one or more selected from the group consisting of silicon, glass, ceramic and equivalents thereof. However, the present disclosure does not limit the material of the stiffener 111 to those disclosed herein. The stiffener 111 generally improves mechanical stiffness of the interposer 110, thereby improving reliability of the semiconductor device 100. The conductive via 112 is formed in the stiffener 111 and electrically connects the redistribution pattern 114 formed on a top surface of the stiffener 111 with the under bump metal 117 formed on the bottom surface of the stiffener 111. The conductive via 112 is generally made of one or more selected from the group consisting of copper, aluminum, gold, silver, and alloys and equivalents thereof, but aspects of the present disclosure are not limited thereto.

The redistribution layer 113 (or redistribution structure) is generally formed on the top surface of the stiffener 111 and includes a redistribution pattern 114 (e.g., one or more conductive layers), a dielectric layer 115 and a micro bump pad 116. The redistribution pattern 114 is electrically connected to the conductive via 112 and may be formed by multiple layers when necessary. In addition, the dielectric layer 115 covers the stiffener 111 and the redistribution pattern 114 and may also be formed by multiple layers when necessary. The micro bump pad 116 is connected to the topmost redistribution pattern 114 but is not covered by the dielectric layer 115 so as to be electrically connected to the semiconductor die 120. Here, the redistribution pattern 114 and the micro bump pad 116 may be made of one or more selected from the group consisting of copper, aluminum, gold, silver, and alloys and equivalents thereof, but aspects of the present disclosure are not limited thereto. In addition, the dielectric layer 115 may be made of one or more selected from the group consisting of silicon oxide, silicon nitride, polyimide, benzocyclobutene, polybenzoxazole and equivalents thereof, but aspects of the present disclosure are not limited thereto.

The under bump metal 117 is formed on the bottom surface of the stiffener 111 and is connected to the conductive via 112. The under bump metal 117 may be made of one or more of at least one selected from the group consisting of chrome, nickel, palladium, gold, silver, and alloys and equivalents thereof, but aspects of the present disclosure are not limited thereto. The under bump metal 117 prevents an intermetallic compound from being formed between (e.g., at the interface of) the conductive via 112 and the conductive bump 150, thereby improving reliability of the conductive bump 150.

The semiconductor die 120 is electrically connected to the redistribution layer 113 (or redistribution structure). To this end, the semiconductor die 120 includes a micro bump 121 (e.g., a die interconnection structure), such as a Cu pillar or a Cu post, and may be electrically connected to the micro bump pad 116 provided in the redistribution layer 113 (or redistribution structure) through a solder 122. The semiconductor die 120 may include, for example, an electrical circuit, such as a digital signal processor (DSP), a microprocessor, a network processor, a power management processor, an audio processor, an RF circuit, a wireless baseband system-on-chip (SoC) processor, a sensor, or an application-specific integrated circuit (ASIC).

The underfill 130 is interposed between the semiconductor die 120 and the interposer 110 and allows the semiconductor die 120 to be mechanically connected to the interposer 110 in a more secure manner. Here, the underfill 130 surrounds the micro bump 121 and the solder 122. In particular, the underfill 130 prevents delamination between the semiconductor die 120 and the interposer 110, thus preventing them from being electrically disconnected from each other due to a difference between coefficients of thermal expansion between the semiconductor die 120 and the interposer 110. In some cases, the underfill 130 may not be provided.

The encapsulant 140 encapsulates the semiconductor die 120 positioned on the top surface of the interposer 110. That is to say, the encapsulant 140 surrounds the underfill 130 and the semiconductor die 120, thereby safely protecting the underfill 130 and the semiconductor die 120 from external circumstances. In some cases, the encapsulant 140 may not cover the top surface of the semiconductor die 120 to make the top surface of the semiconductor die 120 directly exposed to the outside, thereby improving heat emission efficiency of the semiconductor die 120. In other example implementations, the encapsulant 140 may cover the top surface of the semiconductor die 120.

Meanwhile, when a diameter of an inorganic filler forming the encapsulant 140 is smaller than a gap size between the semiconductor die 120 and the interposer 110, the underfill 130 may, for example, not be used. For example, when a molded underfill (MUF) smaller than the gap size is used, two process steps (underfilling and encapsulating) may be reduced to one process step (encapsulating).

The conductive bump 150 may be connected to the under bump metal 117 formed on the bottom surface of the interposer 110 or directly to the conductive via 112. The conductive bump 150 may be made of one selected from the group consisting of a eutectic solder (Sn37Pb), a high lead solder (Sn95Pb), a lead-free solder (SnAg, SnAu, SnCu, SnZn, SnZnBi, SnAgCu, or SnAgBi), and an equivalent thereof, but aspects of the present embodiment are not limited thereto.

As described above, the semiconductor device 100 according to an embodiment of the present disclosure provides the interposer 110 having the redistribution layer 113 (or redistribution structure) formed on the stiffener 111, thereby improving mechanical stiffness of the interposer 110. That is to say, the semiconductor device 100 according to the present disclosure includes the interposer 110 having the redistribution layer 113 (or redistribution structure) formed on the stiffener 111 made of a material having high hardness and/or strength, such as silicon, glass or ceramic, etc., thereby reinforcing the mechanical stiffness of the interposer 110, compared to the conventional interposer, thereby facilitating handling of the interposer 110 in the course of manufacturing the semiconductor device 100 and improving mechanical reliability of the completed semiconductor device 100. In particular, according to various aspects of the present disclosure, the mechanical stiffness of the interposer 110 is reinforced, thereby effectively suppressing interfacial delamination between the under bump metal 117 and the conductive bump 150.

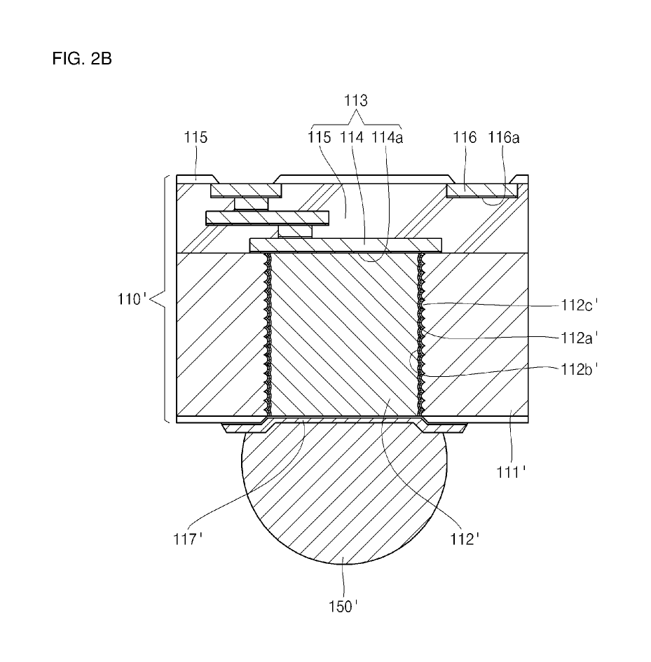

Referring to FIG. 2A, an enlarged cross-sectional view illustrating a conductive via (112) formed in a stiffener (111) using a damascene process is illustrated and referring to FIG. 2B, an enlarged cross-sectional view illustrating a through silicon via (112′) formed on a silicon substrate (111′) using a plasma etching process is illustrated.

As illustrated in FIG. 2A, the conductive via 112 passing through the top and bottom surfaces of the stiffener 111 is formed using the damascene process and a cross section of the conductive via 112 is shaped of a substantially inverted trapezoid. In practice, a top surface diameter of the conductive via 112 (e.g., an end of the conductive via 112 away from the conductive bump 150) is slightly greater than a bottom surface diameter of the conductive via 112 (e.g., an end of the conductive via 112 toward the conductive bump 150). In addition, side surfaces of the conductive via 112 facing each other are substantially planar surfaces of inclination. Note that the conductive via 112 may, for example, be shaped like a truncated cone.

However, as illustrated in FIG. 2B, a cross section of the through silicon via 112′ formed on the silicon substrate 111′ (or other stiffener material) using the plasma etching process has a substantially rectangular shape. That is to say, a top surface diameter of the through silicon via 112′ is substantially the same as a bottom surface diameter of the through silicon via 112′. In addition, due to processing characteristics, a plurality of scallops (or embossing features) 112c′ are formed on opposite side surfaces of the through silicon via 112′. That is to say, the opposite side surfaces of the through silicon via 112′ may, for example, not planar surfaces but may be roughened surfaces having the plurality of scallops or embossing 112c′. Note that the conductive via 112′ may, for example, be shaped like a cylinder.

In addition, while an aspect ratio of the conductive via 112 formed on the stiffener 111 using the damascene process is in a range of about 1:1 to about 1:2, an aspect ratio of the through silicon via 112′ formed on the silicon substrate 111′ using the plasma etching process is in a range of about 1:10 to about 1:15. Therefore, an electrical path of the conductive via 112 according to the present disclosure is much shorter than that of the conventional through silicon via 112′. In addition, a diameter of the conductive via 112 formed on the stiffener 111 using the damascene process may be in a range of about 10 μm to about 20 μm. However, a diameter of the through silicon via 112′ formed on the silicon substrate 111′ using the plasma etching process is 112′ is much greater than 20 μm.

In addition, an insulation layer 112a and a seed layer 112b may further be interposed between the stiffener 111 and the conductive via 112. When the stiffener 111 is made of silicon, the insulation layer 112a may be an inorganic layer, such as a silicon oxide layer or a silicon nitride layer, but aspects of the present disclosure are not limited thereto. Meanwhile, when the stiffener 111 is made of glass or ceramic, the insulation layer 112a may be an organic layer, such as polyimide, benzocyclobutene, or polybenzoxazole, but aspects of the present disclosure are not limited thereto. In addition, the seed layer 112b may generally be made of one selected from the group consisting of titanium/copper, titanium tungsten/copper, and alloys and equivalents thereof, but aspects of the present disclosure are not limited thereto.

Meanwhile, an insulation layer 112a′ and a seed layer 112b′ may also further be interposed between the silicon substrate 111′ and the through silicon via 112′. In this case, due to processing characteristics, a plurality of scallops (or embossing features) 112c′ may still remain on the insulation layer 112a′ and the seed layer 112b′.

That is to say, according to the present disclosure, scallops or embossing are not formed in the conductive via 112 due to processing characteristics, while scallops (or embossing features) still remain on the through silicon via 112′ due to conventional processing characteristics.

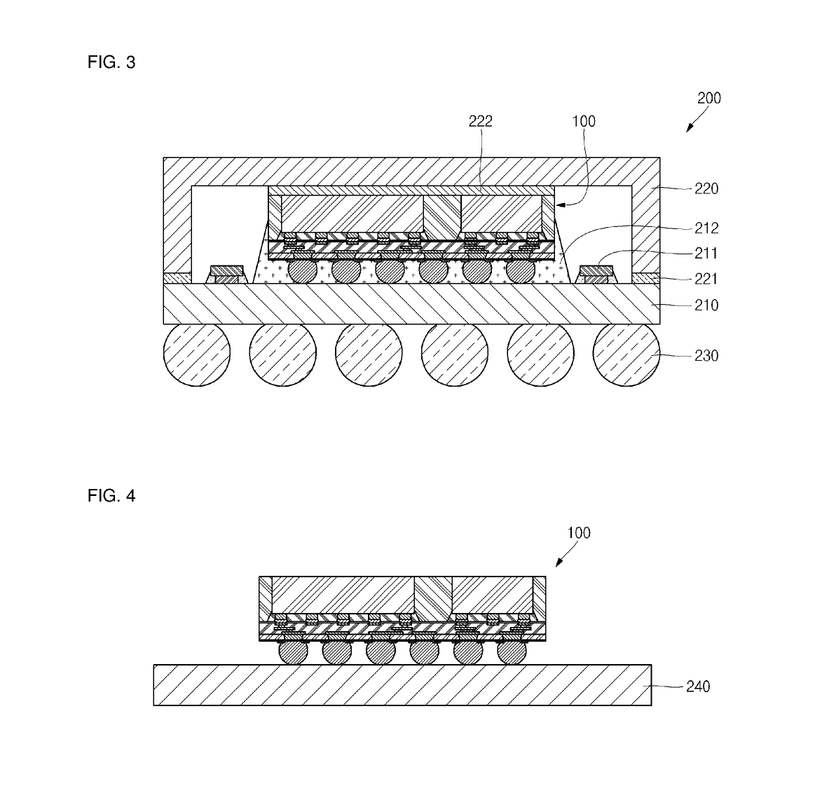

Referring to FIG. 3, a cross-sectional view of a semiconductor device 200 according to another embodiment of the present disclosure is illustrated.

As illustrated in FIG. 3, the semiconductor device 200 according to another embodiment of the present disclosure may further include a circuit board 210, a lid 220 and a conductive ball 230.

That is to say, the semiconductor device 100 is electrically connected to the circuit board 210 through a conductive bump 150. Various passive elements 211 may further be mounted on the circuit board 210 when necessary. Moreover, an underfill 212 may be interposed between the semiconductor device 100 and the circuit board 210 when necessary. In addition, the lid 220 covers the semiconductor device 100 and the passive elements 211 mounted on the circuit board 210, thereby protecting the semiconductor device 100 and the passive elements 211 from external circumstances. In addition, the conductive ball 230 is electrically connected to the circuit board 210 and is mounted on an external device (e.g., a main board or a mother board). Here, the lid 220 may be adhered to the circuit board 210 using an adhesive 221 and/or may be adhered to the semiconductor device 100 using the adhesive 222 (e.g., a thermally conductive adhesive, etc.).

Referring to FIG. 4, a cross-sectional view of a semiconductor device 100 according to still another embodiment of the present disclosure is illustrated.

As illustrated in FIG. 4, the semiconductor device 100 according to still another embodiment of the present disclosure may be directly mounted on an external device 240, such as a main board or a mother board, rather than on the circuit board 210.

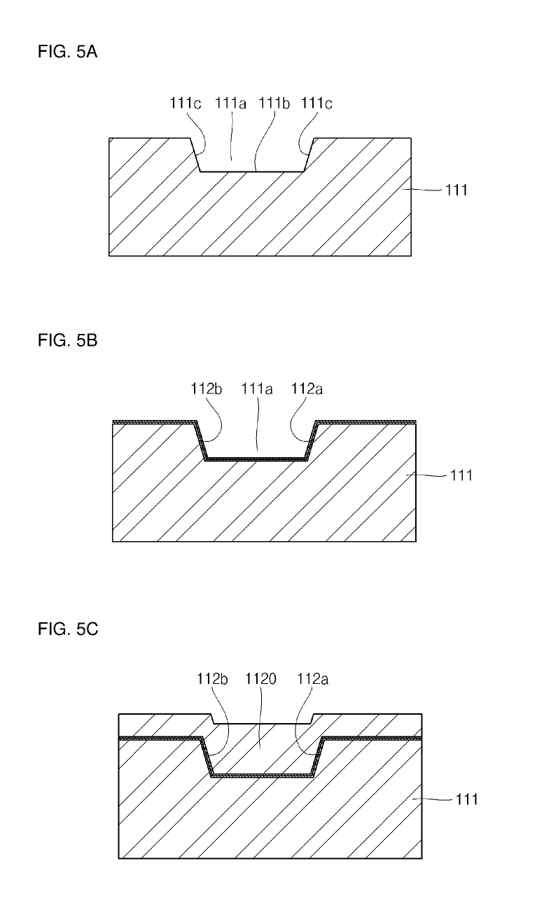

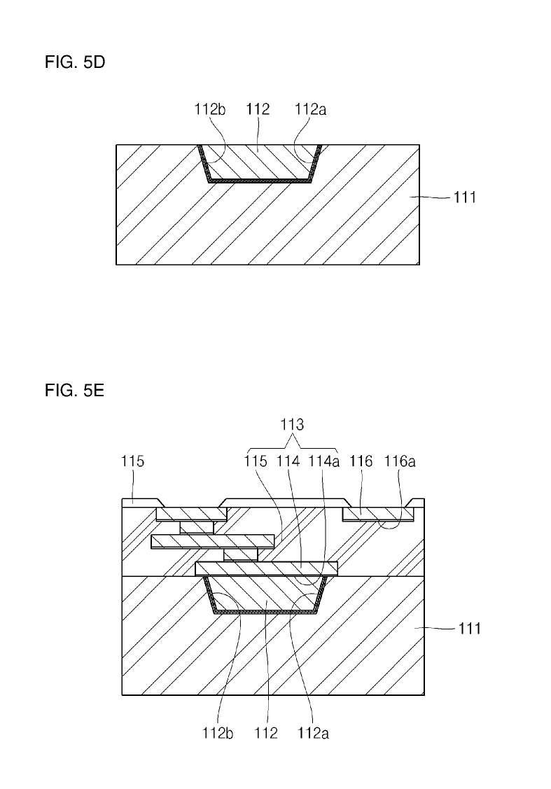

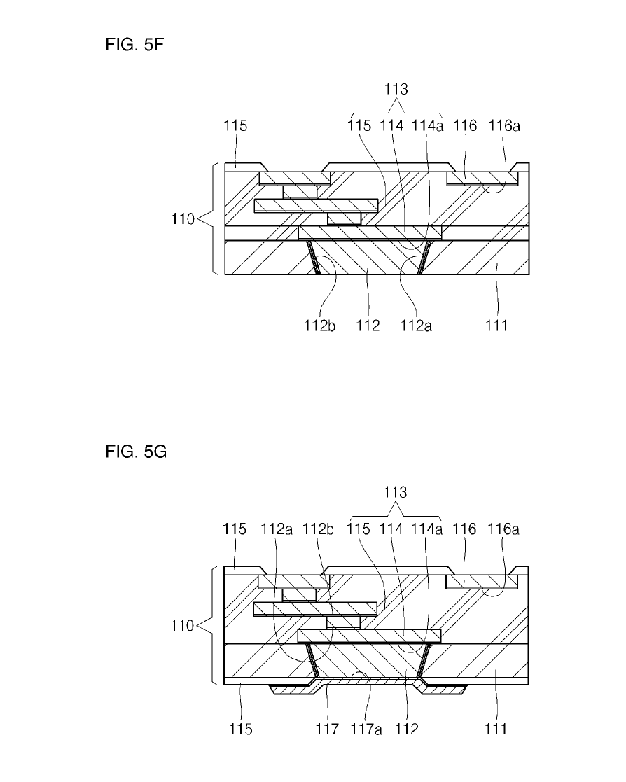

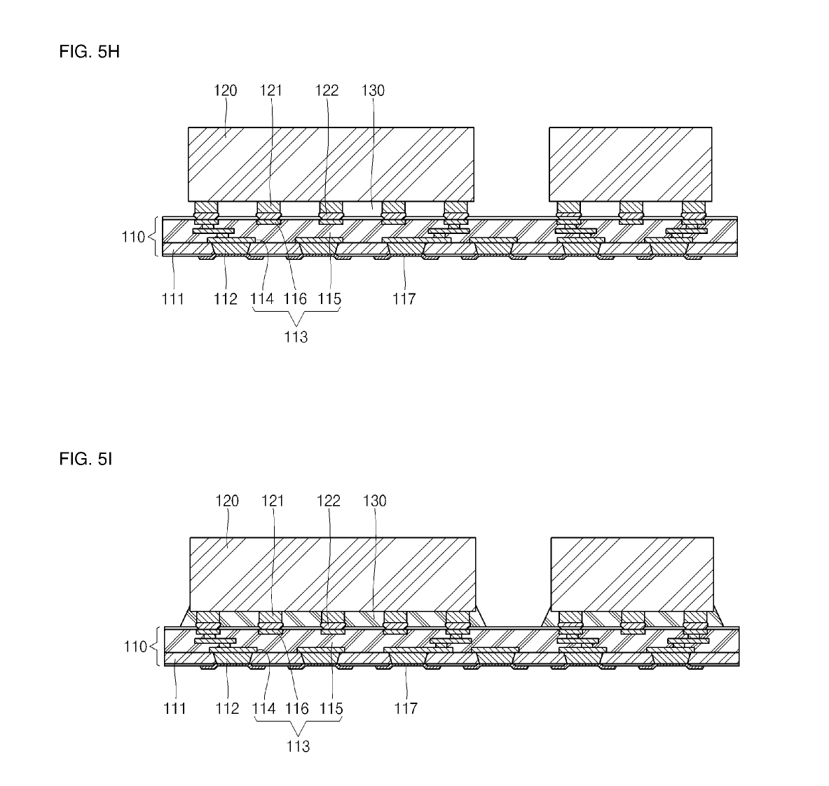

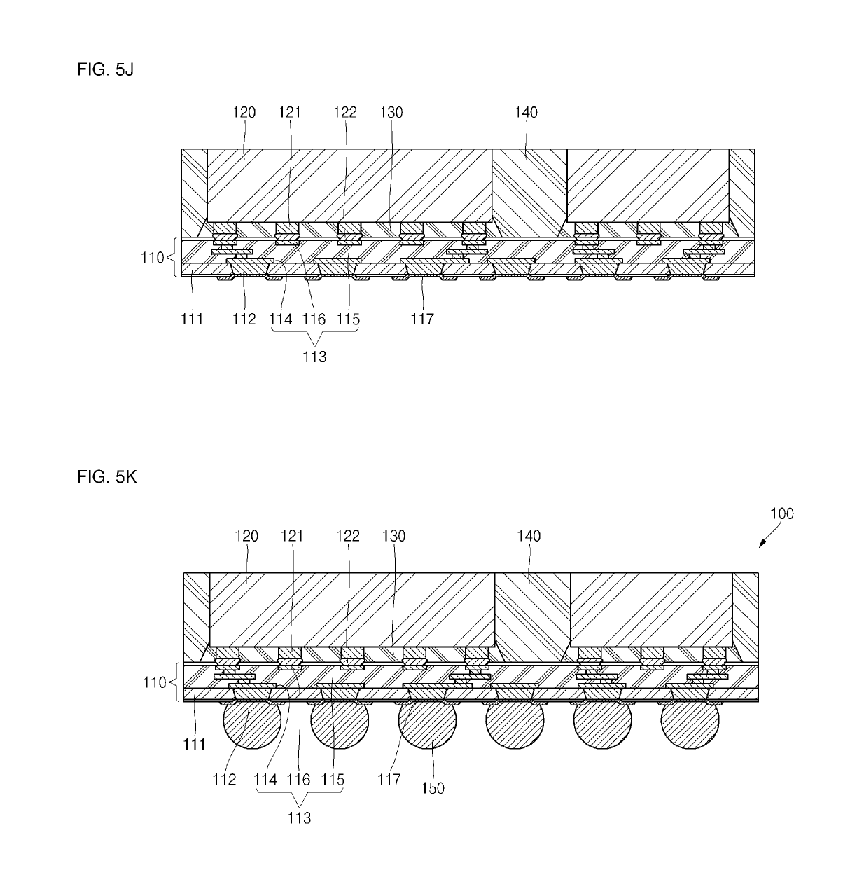

Referring to FIGS. 5A to 5K, cross-sectional views sequentially illustrating a method of manufacturing a semiconductor device 100 according to still another embodiment of the present disclosure are illustrated.

As illustrated in FIG. 5A, a trench 111a having a predetermined depth is formed in a stiffener 111. Since the trench 111a is generally formed using a relatively inexpensive etching process, a cross section of the trench 111a is shaped of a substantially inverted trapezoid. That is to say, the cross section of the trench 111a has a bottom surface 111b and opposite side surfaces 111c. Here, the bottom surface 111b may be planar in a substantially horizontal direction and the opposite side surfaces 111c may be substantially vertically planar surfaces of inclination. In other words, the trench 111a is configured to have a smaller diameter as its depth increases. The cross section of the trench 111a is attributed to anisotropic etching characteristics generated during the etching process.

As illustrated in FIG. 5B, an insulation layer 112a and a seed layer 112b are sequentially formed in the trench 111a and exterior regions of the trench 111a. Here, when the stiffener 111 is made of silicon, the insulation layer 112a may be an inorganic layer, such as a silicon oxide layer or a silicon nitride layer, but aspects of the present disclosure are not limited thereto. Meanwhile, when the stiffener 111 is made of glass or ceramic, the insulation layer 112a may be an organic layer, such as polyimide, benzocyclobutene, or polybenzoxazole, but aspects of the present disclosure are not limited thereto.

In an exemplary embodiment, an inorganic layer, such as a silicon oxide layer or a silicon nitride layer, may be formed to have a predetermined thickness by supplying oxygen gas and/or nitrogen gas to silicon in an atmosphere of about 900° C. or higher, but aspects of the present disclosure are not limited thereto.

In another exemplary embodiment, an organic layer, such as a polyimide layer, may be formed by spin coating, spray coating, dip coating or rod coating, but aspects of the present disclosure are not limited thereto.

Meanwhile, the seed layer 112b may be made of titanium/copper, titanium tungsten/copper, or the like, but the scope of the present disclosure is not limited thereto. The seed layer 112b may be formed by, for example, electroless plating, electrolytic plating and/or sputtering, but aspects of the present disclosure are not limited thereto.

As illustrated in FIG. 5C, a conductive layer 1120 having a predetermined thickness may be formed in the trench 111a having the insulation layer 112a and the seed layer 112b formed therein and exterior regions of the trench 111a. The conductive layer 1120 may be made of copper, aluminum, gold or silver, but aspects of the present disclosure are not limited thereto. Meanwhile, the conductive layer 1120 may be formed by, for example, electroless plating, electrolytic plating and/or sputtering, but aspects of the present disclosure are not limited thereto.

As illustrated in FIG. 5D, a predetermined portion of the conductive layer 1120 formed in the trench 111a and exterior regions of the trench 111a may be removed by a planarizing process or a chemical mechanical polishing (CMP) process, for example. In an exemplary embodiment, the conductive layer 1120 formed in the exterior regions of the trench 111a positioned at an upper side of the stiffener 111 is completely removed, so that the conductive layer 1120 may remain only within the trench 111a. Hereinafter, the conductive layer 1120 will be referred to as the conductive via 112.

As illustrated in FIG. 5E, one or more layers of a redistribution pattern 114 (e.g., a conductive layer) and a dielectric layer 115 are formed on the stiffener 111 and a micro bump pad 116 is formed on the topmost redistribution pattern 114, thereby completing the redistribution layer 113 (or redistribution structure). That is to say, a redistribution seed layer pattern 114a is formed to be connected to the conductive via 112 of the stiffener 111, the redistribution pattern 114 is formed on the redistribution seed layer pattern 114a, and the redistribution pattern 114 is finished with the dielectric layer 115. In addition, a pad seed layer 116a is formed on the topmost redistribution pattern 114 and the micro bump pad 116 is then formed on the pad seed layer 116a. Here, the micro bump pad 116 is not covered by the dielectric layer 115 but is exposed to the outside so as to be electrically connected to the semiconductor die 120 in a subsequent processing step.

Here, the redistribution seed layer pattern 114a and the pad seed layer 116a may be made of titanium/copper, titanium tungsten/copper, or the like using a general process of electroless plating, electrolytic plating or sputtering, but the scope of this disclosure is not limited to such materials and/or such processes. In addition, the redistribution layer 113 (or redistribution structure) and the micro bump pad 116 may be made of copper, aluminum, gold or silver using electroless plating, electrolytic plating or sputtering and/or photolithography, but the scope of this disclosure is not limited to such materials and/or such processes. In addition, the dielectric layer 115 may be made of polyimide, benzocyclobutene, or polybenzoxazole using spin coating, spray coating, dip coating, or rod coating, but the scope of this disclosure is not limited to such materials and/or such processes.

As illustrated in FIG. 5F, a lower region of the trench 111a in the stiffener 111 is removed using a planarizing process or a CMP process, but the scope of this disclosure is not limited thereto. Therefore, a bottom surface of the conductive via 112 formed in the trench 111a is exposed to the outside. At this time, the insulation layer 112a and the seed layer 112b formed on the bottom surface of the conductive via 112 may also be removed. That is to say, the planarizing process or the CMP process may allow the conductive via 112, for example, a bottom surface of copper, to be directly exposed downward. Here, the bottom surface of the stiffener 111 and the bottom surface of the conductive via 112 are coplanar (or coplanarly positioned).

As illustrated in FIG. 5G, an under bump metal 117 is formed in the conductive via 112 exposed through the bottom surface of the stiffener 111. That is to say, a metal seed layer 117a is formed on the bottom surface of the conductive via 112 and the under bump metal 117 is then formed on the metal seed layer 117a. The metal seed layer 117a may be made of titanium/copper, titanium tungsten/copper, or the like using a general process of electroless plating, electrolytic plating or sputtering, but the scope of this disclosure is not limited to such materials and/or such processes. In addition, the under bump metal 117 may be made of at least one selected from the group consisting of chrome, nickel, palladium, gold, silver, and alloys and equivalents thereof, but aspects of the present disclosure are not limited thereto. In addition, the under bump metal 117 may also be formed using a general process of electroless plating, electrolytic plating and/or sputtering, but the scope of this disclosure is not limited thereto. The under bump metal 117 prevents an intermetallic compound from being formed between (e.g., at the interface of) the conductive via 112 and a conductive bump 150 to be described below, thereby improving board-level reliability of the conductive bump 150. In addition, when necessary, a dielectric layer 115 may further be formed between the under bump metal 117 and the stiffener 111. In some cases, the under bump metal 117 may not be provided.

In such a manner, the interposer 110, including the stiffener 111 having the conductive via 112 and the redistribution layer 113 (or redistribution structure) including the redistribution pattern 114, the dielectric layer 115, the micro bump pad 116 and the under bump metal 117, is completed.

As illustrated in FIG. 5H, at least one semiconductor die 120 is electrically connected to the interposer 110. In an exemplary embodiment, the semiconductor die 120 may be electrically connected to the micro bump pad 116 of the interposer 110 through a micro bump 121 and a solder 122. In an exemplary embodiment, volatile flux is dotted on the micro bump pad 116 of the interposer 110 and the semiconductor die 120 having the micro bump 121 is aligned thereon. Thereafter, if a temperature in a range of about 150° C. to about 250° C. is applied, the micro bump 121 is fused with the micro bump pad 116 while the solder 122 formed at a bottom end of the micro bump 121 is melted. Next, the resultant product is subjected to a cooling process to allow the solder 122 formed at the bottom end of the micro bump 121 to be cured, thereby completing electrically and mechanically connecting of the semiconductor die 120 to the interposer 110. Alternatively, the method of connecting the semiconductor die 120 to the interposer 110 can be embodied in various manners.

As illustrated in FIG. 51, an underfill 130 is filled in a gap or space between the semiconductor die 120 and the interposer 110. For example, the underfill 130 contained in a dispenser is dispensed to the gap between the semiconductor die 120 and the interposer 110, followed by curing, thereby mechanically connecting the semiconductor die 120 and the interposer 110 to each other by the underfill 130.

In some cases, the filling of the underfill 130 may not be performed.

As illustrated in FIG. 5J, the semiconductor die 120 formed on the top surface of the interposer 110 and the underfill 130 are encapsulated by the encapsulant 140. Here, a top surface of the semiconductor die 120 may be exposed to the outside through the encapsulant 140. The encapsulant 140 may, for example, surround the underfill 130 if formed. Also for example, a portion of the encapsulant 140 may underfill the semiconductor die 120 as a molded underfill.

As illustrated in FIG. 5K, the conductive bump 150 is connected to the under bump metal 117 formed on the bottom surface of the interposer 110. In an exemplary embodiment, volatile flux is dotted on the under bump metal 117 and the conductive bump 150 is temporarily positioned thereon. Thereafter, if a temperature in a range of about 150° C. to about 250° C. is applied, the conductive bump 150 is melted and fused with the under bump metal 117. Next, the resultant product is subjected to a cooling process to allow the conductive bump 150 to be cured, thereby completing electrically and mechanically connecting of the conductive bump 150 to the interposer 110. In addition, various methods can be employed to connect the semiconductor die 120 to the interposer 110.

Here, the method of connecting the conductive bump 150 to the interposer 110 can be performed in various manners.

In addition, the aforementioned process may be performed on a basis of a unit, a panel, a strip, a wafer or a matrix. When the process is performed on the basis of the panel, the strip, the wafer or the matrix, it may be followed by a sawing process. That is to say, the individual semiconductor device 100 is singulated from the panel, the strip, the wafer or the matrix by a sawing or punching process.

As described above, according to the present disclosure, the conductive via 112 is formed using a relatively inexpensive damascene process, instead of a through silicon via formed using a relatively expensive plasma etching process or laser drilling process, thereby providing the semiconductor device 100 including the interposer 110 formed at low cost. That is to say, according to the present disclosure, the trench 111a is formed in the stiffener 111 and the conductive layer 1120 is then filled in the trench 111a, followed by removing a region of the stiffener 111 using a planarization process or a grinding process, thereby completing the conductive via 112 electrically connecting the top and bottom surfaces of the stiffener 111. Therefore, according to the present disclosure, the conductive via 112 capable of performing the same function as the conventional through silicon via can be manufactured at low cost without using the relatively inexpensive priced plasma etching or laser drilling process.

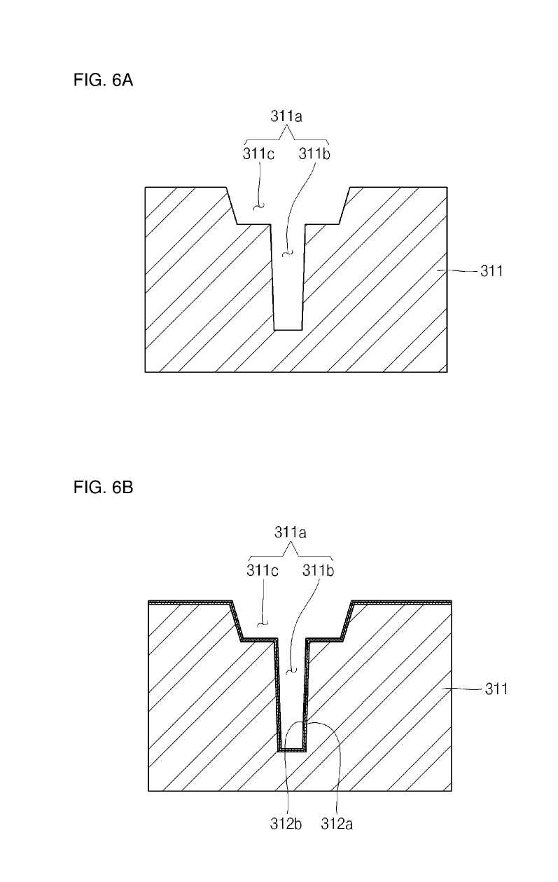

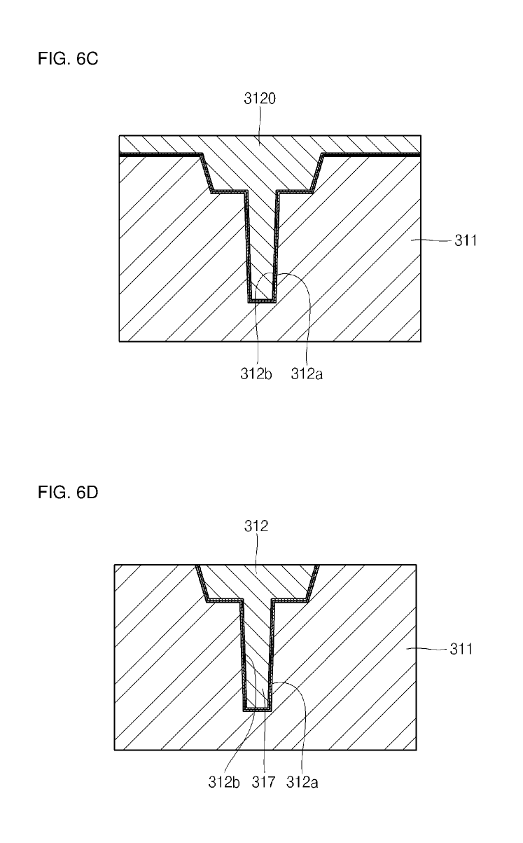

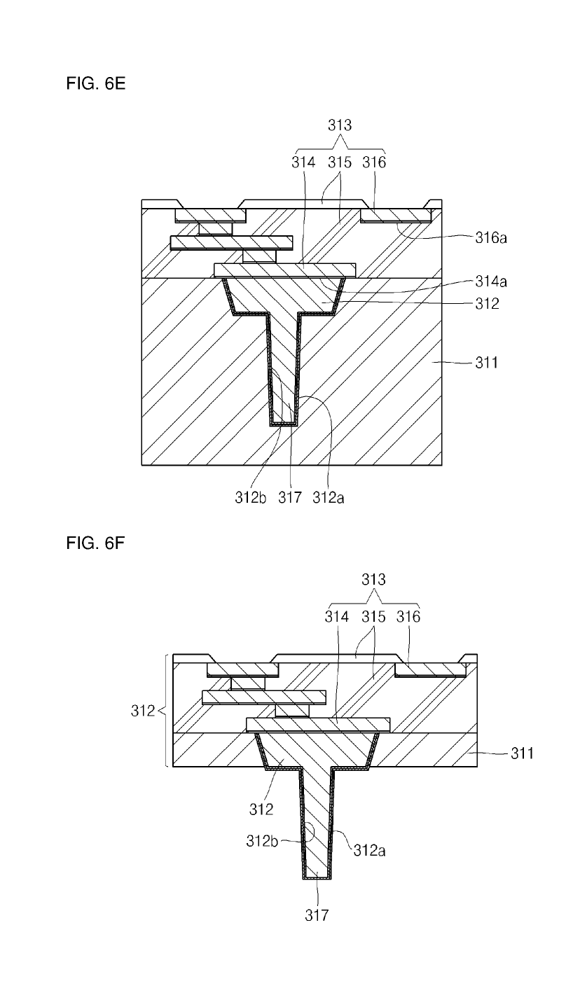

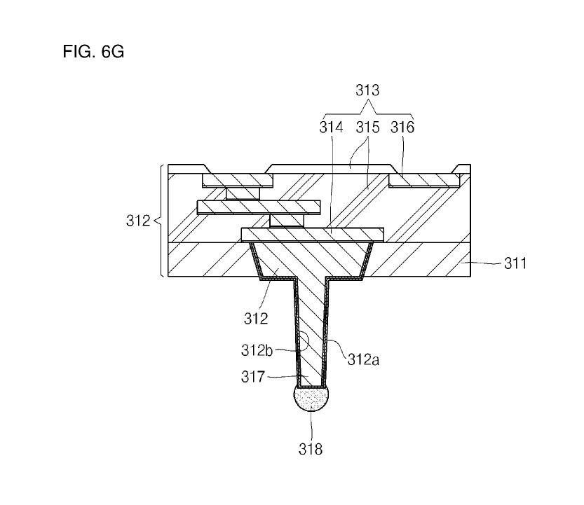

Referring to FIGS. 6A to 6G, cross-sectional views sequentially illustrating a method of manufacturing a semiconductor device according to still another embodiment of the present disclosure are illustrated. Here, since a semiconductor die, an underfill and an encapsulant formed on a redistribution layer (or redistribution structure) are the same as those of the previous embodiment(s), repeated description thereof will not be given.

As illustrated in FIG. 6A, a dual trench 311a having a predetermined depth is formed in a stiffener 311. That is to say, a first trench 311b, which is relatively deep and narrow, is formed in the stiffener 311 and a second trench 311c, which is relatively shallow and wide, is formed on the first trench 311b. Since the dual trench 311a is formed by a general photolithography process, a cross section of the dual trench 311a may be shaped of two inverted trapezoids.

As illustrated in FIG. 6B, an insulation layer 312a and a seed layer 312b are sequentially formed in the dual trench 311a and exterior regions of the dual trench 311a. Here, when the stiffener 311 is made of silicon, the insulation layer 312a may be an inorganic layer, such as a silicon oxide layer or a silicon nitride layer, but the scope of this disclosure is not limited thereto. When the stiffener 311 is made of glass or ceramic, the insulation layer 312a may be an organic layer, such as polyimide, benzocyclobutene, or polybenzoxazole, but the scope of this disclosure is not limited thereto.

As illustrated in FIG. 6C, a conductive layer 3120 having a predetermined thickness may be formed in the dual trench 311a having the insulation layer 312a and the seed layer 312b formed therein and exterior regions of the dual trench 311a.

As illustrated in FIG. 6D, a predetermined portion of the conductive layer 3120 formed in the dual trench 311a and the exterior regions of the dual trench 311a to a predetermined thickness may be removed by a planarizing process or a chemical mechanical polishing (CMP) process, but the scope of this disclosure is not limited thereto. In an exemplary embodiment, the conductive layer 3120 formed in the exterior regions of the dual trench 31 la positioned at an upper side of the stiffener 311 is completely removed, so that the conductive layer 3120 may remain only within the dual trench 311a. Here, the conductive layer 3120 filled in the first trench 311b may turn into a conductive pillar 317 in a later process and the conductive layer 3120 filled in the second trench 311c may turn into a conductive via 312 in a later process. Hereinafter, the conductive layer 3120 will be referred to as the conductive pillar 317 and the conductive via 312.

As illustrated in FIG. 6E, one or more layers (e.g., conductive layers) of a redistribution pattern 314 and a dielectric layer 315 may be formed on the stiffener 311, and a micro bump pad 316 is formed on the topmost redistribution pattern 314, thereby completing the redistribution layer 313 (or redistribution structure). That is to say, a redistribution seed layer 314a is formed to be connected to the conductive via 312 of the stiffener 311, the redistribution pattern 314 is formed on the redistribution seed layer 314a, and the redistribution pattern 314 is covered by dielectric layer 315. In addition, a pad seed layer 316a is formed on the topmost redistribution pattern 314 and the micro bump pad 316 is then formed on the pad seed layer 316a.

As illustrated in FIG. 6F, a lower region of the first trench 311b formed in the stiffener 311 may be removed by a planarizing process or a chemical mechanical polishing (CMP) process. In addition, exterior regions of the first trench 311b formed in the stiffener 311, that is, exterior regions of the conductive pillar 317, are removed, thereby providing the conductive pillar 317 configured to extend a predetermined length downwardly from the conductive via 312. For example, in an example implementation in which the stiffener 311 is made from silicon, a silicon etching process may be used to reduce the thickness of the stiffener 311 so that the conductive pillar 317 (e.g., the entire pillar 317, or a portion thereof) protrudes from the bottom side of the stiffener 311. Note that bottom side of the conductive via 312 may be coplanar with the stiffener 311 at this point, may protrude from the stiffener 311 at this point, or may be covered by the stiffener 311 at this point. In an example implementation, the conductive via 312 is configured to be positioned within the stiffener 311 and the conductive pillar 317 is configured to extend a predetermined length downwardly from the stiffener 311.

As illustrated in FIG. 6G, the insulation layer 312a positioned on a bottom surface of the conductive pillar 317 is removed, thereby electrically connecting a solder 318 to the bottom surface of the conductive pillar 317. The seed layer 312b positioned on a bottom surface of the conductive pillar 317 may remain or may be removed when necessary.

In addition, the solder 318 may be formed after attaching a semiconductor die onto an interposer 310 and applying an underfill and an encapsulant to the resultant product. In addition, since the semiconductor die, the underfill and the encapsulant are the same as those of the previous embodiment, repeated descriptions of forming processing steps and configurations thereof will not be given.

As described above, according to the present disclosure, the conductive pillar 317 having a fine pitch can be formed by forming the conductive pillar 317 on the interposer 310 using the damascene process. That is to say, the dual trench 311a is formed in the stiffener 311, the conductive layer 3120 is filled in the dual trench 311a, and a predetermined region of the stiffener 311 is removed by a planarizing or grinding process and an etching process, thereby achieving the conductive via 312 connecting top and bottom surfaces of the stiffener 311 and the conductive pillar 317 integrally formed in the conductive via 312. Therefore, according to the present disclosure, the conductive pillar 317 having a fine pitch can be formed at low cost.

The discussion herein included numerous illustrative figures that showed various portions of an electronic device assembly and method of manufacturing thereof. For illustrative clarity, such figures did not show all aspects of each example assembly. Any of the example assemblies and/or methods provided herein may share any or all characteristics with any or all other assemblies and/or methods provided herein.

In summary, various aspects of this disclosure provide a semiconductor device and a method of manufacturing a semiconductor device. As a non-limiting example, various aspects of this disclosure provide a semiconductor device, and method of manufacturing thereof, that comprises a redistribution structure formed on a stiffening layer. While the foregoing has been described with reference to certain aspects and examples, it will be understood by those skilled in the art that various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular example(s) disclosed, but that the disclosure will include all examples falling within the scope of the appended claims.

What is claimed is:

1. A semiconductor device comprising:
an interposer comprising:
a stiffener layer comprising a top stiffener surface, a bottom stiffener surface, and a conductive via that extends from the top stiffener surface to the bottom stiffener surface; and
a redistribution structure comprising a top redistribution structure surface, and a bottom redistribution structure surface coupled to the top stiffener surface; and
a semiconductor die connected to the top redistribution structure surface.

2. The semiconductor device of claim 1, wherein the stiffener layer comprises: a silicon layer, a glass layer, and/or a ceramic layer.

3. The semiconductor device of claim 1, wherein the conductive via has a cross-section shaped like an inverted trapezoid with a top via end at the top stiffener surface wider than a bottom via end at the bottom stiffener surface.

4. The semiconductor device of claim 1, wherein a top via surface of the conductive via has a greater diameter than a bottom via surface of the conductive via.

5. The semiconductor device of claim 1, comprising a seed layer and an insulation layer between the conductive via and the stiffener.

6. The semiconductor device of claim 1, further comprising a conductive bump coupled to a bottom via end of the conductive via.

7. The semiconductor device of claim 6, further comprising an under bump metal between the conductive via and the conductive bump.

8. The semiconductor device of claim 1, wherein a side surface of the conductive via comprises scallops.

9. The semiconductor device of claim 1, comprising an insulation layer surrounding a side surface of the conductive via, wherein the insulation layer comprises scallops.

10. A semiconductor device comprising:
an interposer comprising:
a stiffener layer comprising a top stiffener surface, a bottom stiffener surface, and a conductive via that extends from the top stiffener surface to the bottom stiffener surface;
a redistribution structure comprising a top redistribution structure surface, and a bottom redistribution structure surface coupled to the top stiffener surface; and
a conductive pillar extending from a bottom via surface of the conductive via; and
a semiconductor die connected to the top redistribution structure surface.

11. The semiconductor device of claim 10, wherein the entire conductive pillar has a smaller width than a width of the conductive via.

12. The semiconductor device of claim 11, wherein the conductive pillar has a cross-section shaped like an inverted trapezoid with a top pillar end wider than a bottom pillar end.

13. The semiconductor device of claim 12, wherein the conductive via has a cross-section shaped like an inverted trapezoid with a top via end wider than a bottom via end.

14. The semiconductor device of claim 10, wherein the bottom conductive pillar extends from the bottom stiffener surface.

15. The semiconductor device of claim 10, comprising a conductive bump coupled to a bottom pillar end of the conductive pillar.

16. The semiconductor device of claim 10, wherein the conductive via and the conductive pillar are integrally formed with each other.

17. The semiconductor device of claim 10, comprising a seed layer and an insulation layer, wherein:
a first portion of the seed layer and a first portion of the insulation layer are between the conductive via and the stiffener; and
a second portion of the seed layer and a second portion of the insulation layer are between the conductive pillar and the stiffener.

18. The semiconductor device of claim 10, wherein the entire conductive pillar extends from the bottom stiffener surface.

19. A method of manufacturing a semiconductor device, the method comprising:
providing an interposer comprising:
a stiffener layer comprising a top stiffener surface, a bottom stiffener surface, and a conductive via that extends from the top stiffener surface to the bottom stiffener surface; and
a redistribution structure comprising a top redistribution structure surface, and a bottom redistribution structure surface coupled to the top stiffener surface; and
attaching a semiconductor die to the top redistribution structure surface.

20. The method of claim 19, wherein the interposer comprises a conductive pillar extending from a bottom via surface of the conductive via.
